(19) United States
(12) Patent Application Publication
(10) Pub. No.: US 2010/0167459 A1
(43) Pub. Date: Jul. 1, 2010

(54) METHOD FOR FABRICATING CMOS IMAGE SENSOR

(76) Inventor: Chung-Kyoung Jung, Anyangi-si (KR)

Correspondence Address: SHERR & VAUGHN, PLLC, 620 HERNDON PARKWAY, SUITE 320, HERNDON, VA, 20170, US

(21) Appl. No.: 12/648,829

(22) Filed: Dec. 29, 2009

(30) Foreign Application Priority Data
Dec. 29, 2008 (KR) 10-2008-0135281

(51) Int. Cl. H01L 31/18

(52) U.S. Cl. 438/73; 438/57; 257/E31.001

(57) ABSTRACT

A method for fabricating a CMOS image sensor which reduces occurrence of a dark current. The method includes forming a photodiode in a semiconductor substrate, forming an insulating film over and contacting the semiconductor substrate and the photodiode, respectively, forming a hard mask film over and contacting the insulating film, exposing an area of the insulating film corresponding spatially to the photodiode by performing a first etching process on the hard mask film, and then forming a trench in the insulating film by performing a second etching process using the etched hard mask film as a mask.

The present application claims priority under 35 U.S.C. §119 to Korean Application No. 10-2008-0135281 (filed on Dec. 29, 2008), which is hereby incorporated by reference in its entirety.

### BACKGROUND

Generally, image sensors are semiconductor devices for converting an optical image into an electric signal. Image sensors may be classified as charge coupled devices (CCD) image sensors and complementary metal oxide silicon (CMOS) image sensors.

The CCD has a matrix of photodiodes PD each for converting an optical image into an electric signal. The CCD is provided with a plurality of vertical charge coupled devices VCCD, a horizontal charge coupled device HCCD, and a sense amplifier. The plurality of the VCCDs are formed between the matrix of vertical direction photodiodes for transmission of charges generated at the photodiodes in the vertical direction. The HCCD transmits the charges from the vertical charge coupled devices in a horizontal direction, and the sense amplifier senses the charges transmitted in the horizontal direction to generate an electric signal.

The CCD, however, not only has a complicate driving system and a great power consumption, but also complicated fabrication processes requiring multi-photo steps. Moreover, the CCD has difficulty in reducing the size of the device due to difficulty of integration of control circuits, signal processing circuits, analog/digital converting circuits, etc. in a single CCD chip.

Recently, in order to overcome the drawbacks of the CCD, the CMOS sensor has been used as a next generation image sensor. The CMOS image sensor is a device which employs a switching system in which MOS transistors are formed on and/or over a semiconductor substrate in a number equal to the number of unit pixels using CMOS technology in which the control circuit, the signal processing circuit, etc. are used as peripheral circuits for detecting outputs from the unit pixels in succession. Meaning, by forming the photodiode and the MOS transistor within a unit pixel, the CMOS image sensor detects an electric signal from each unit pixel in succession by the switching system to produce an image. Since the CMOS image sensor uses CMOS fabrication technology, the CMOS image sensor has advantages of comparatively low power consumption, and a simple fabrication process owing to comparatively small number of steps. Moreover, since the control circuit, the signal processing circuit and the analog/digital converting circuit can be integrated onto a CMOS image sensor chip, the CMOS image sensor can be made smaller. Accordingly, the CMOS image sensor is widely used presently in a variety of fields, such as digital still camera, digital video camera, etc.

In general, the CMOS image sensor is provided with a device isolating film formed on and/or over the semiconductor substrate for defining an active region, photodiodes formed on and/or over a surface of the active region of the semiconductor substrate, a plurality of interlayer insulating films and metal lines formed on and/or over an entire surface of the semiconductor substrate, and micro-lenses for focusing lights through color filters.

### SUMMARY

Embodiments are related to a method for fabricating a CMOS image sensor which reduces a dark current.

In accordance with embodiments, a method for fabricating a CMOS image sensor can include at least one of the following: forming a plurality of photodiodes in a semiconductor substrate at fixed intervals, forming an interlayer insulating film on and/or over an entire surface of the semiconductor substrate including the photodiodes, forming a hard mask film on and/or over an entire surface of the interlayer insulating film, forming a photoresist pattern on and/or over the hard mask film for exposing a hard mask film region opposite to a photodiode region, etching the hard mask film by first etching with the photoresist pattern used as a mask, and then selectively etching the interlayer insulating film by second etching with the hard mask film etched thus used as a mask.

In accordance with embodiments, a method for fabricating a CMOS image sensor can include at least one of the following: forming a plurality of photodiodes in a semiconductor substrate at fixed intervals; forming an interlayer insulating film over an entire surface of the semiconductor substrate including the photodiodes; forming a hard mask film over an entire surface of the interlayer insulating film; forming a photoresist pattern over the hard mask film for exposing a hard mask film region corresponding to a photodiode region; etching the hard mask film by performing a first etching process using the photoresist pattern as a mask; and then selectively etching the interlayer insulating film by performing a second etching process using the etched hard mask film as a mask.

In accordance with embodiments, a method for fabricating a CMOS image sensor can include at least one of the following: forming a photodiode in a semiconductor substrate; forming an insulating film over and contacting the semiconductor substrate and the photodiode, respectively; forming a hard mask film over and contacting the insulating film; exposing an area of the insulating film corresponding spatially to the photodiode by performing a first etching process on the hard mask film; and then forming a trench in the insulating film by performing a second etching process using the etched hard mask film as a mask.

In accordance with embodiments, a method for fabricating a CMOS image sensor can include at least one of the following: forming a photodiode in a semiconductor substrate; forming an oxide film over the semiconductor substrate and the photodiode, respectively; forming a hard mask film over the oxide film; exposing an area of the oxide film corresponding spatially to the photodiode by performing a dry etching process on the hard mask film; and then forming a trench by performing a wet etching process on the oxide film.

### DRAWINGS

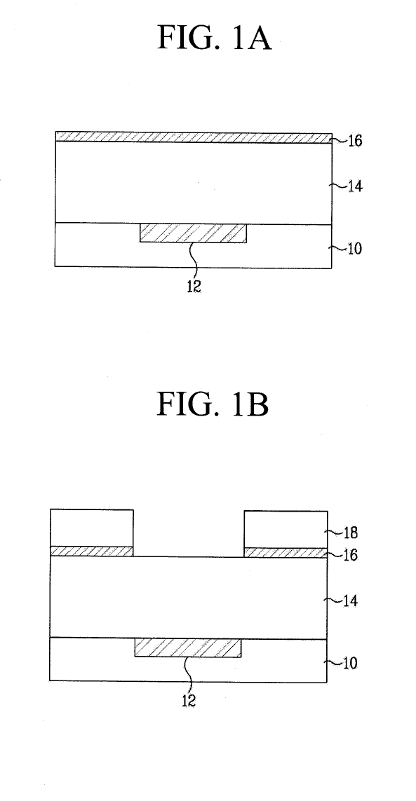

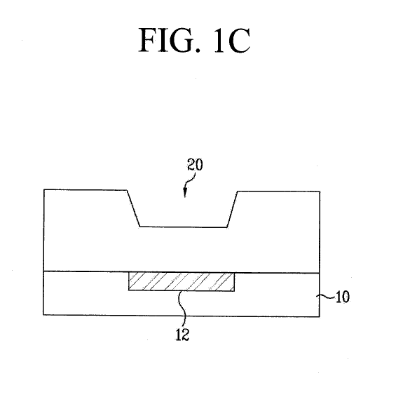

Example FIGS. 1A to 1C illustrate a method for fabricating a CMOS image sensor, in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts. A system and operation of embodiments illustrated in drawings and described with reference thereto is described. However, the description does not limit a technical aspect and essential system and operation of embodiments.

Example FIGS. 1A to 1C illustrate only regions of a CMOS image sensor in accordance with embodiments. Because the other regions can be the same as those provided in a general CMOS sensor, such other regions will be omitted.

As illustrated in example FIG. 1A, a device isolation film is Banned in semiconductor substrate 10 at a device isolation region for defining the active region. The device isolation film is formed by shallow trench isolation (STI) or local oxidation of silicon (LOCOS). Semiconductor substrate 10 can be a p++ type that is subjected to an epitaxial process to form a low concentration, first conduction type, for example, a P type epitaxial layer. Semiconductor substrate 10 may be a single crystalline substrate. The epitaxial layer enables formation of a depletion region deep and large in a photodiode for increasing overall operability and enhancing optical sensitivity of a low voltage photodiode for collecting optical charges.

Impurity ions are injected lightly into the active region of semiconductor substrate 10 between the device isolation films lightly to form photodiode 12 in a surface of semiconductor substrate 10. Interlayer insulating film 14 is then formed on and/or over an entire surface of semiconductor substrate 10 including photodiode 12 and the device isolation film. Interlayer insulating film 14 may be an oxide film, such as undoped silicate glass (USG). Interlayer insulating film 14 may be multi-layered and have a plurality of metal lines formed at fixed intervals. Interlayer insulating film 14 may also have a light shielding layer formed therein for preventing the light from being incident onto portions excluding photodiode 12. Hard mask film 16 is then deposited on and/or over an entire surface of interlayer insulating film 14. Hard mask film 16 can be formed of PE-Nitride.

As illustrated in example FIG. 1B, photoresist is deposited on and/or over hard mask film 16, and subjected to exposure and development to remove the photoresist for forming photoresist pattern 18. Photoresist pattern 18 exposes a portion of hard mask film 16 corresponding spatially to a photodiode region where photodiode 12 is located. Hard mask film 16 is then etched by dry etching using photoresist pattern 18 as a mask to expose a portion of interlayer insulating film 14 corresponding spatially to a photodiode region where photodiode 12 is located.

As illustrated in example FIG. 1C, interlayer insulating film 14 is then etched selectively by wet etching using hard mask film 16 as an etch mask to form trench 20 in interlayer insulating film 14 corresponding spatially to a photodiode region where photodiode 12 is located. The wet etching is performed selectively with DHF at a ratio of H₂0:HF=1 to 5:1. The thickness of hard mask film 16 may be controlled to a thickness which can be removed depending on an etching thickness of interlayer insulating film 14. Tingible photoresist is then coated on and/or over interlayer insulating film 14, and subjected to exposure and development for forming color filter layers at fixed intervals at positions corresponding spatially to a respective one of photodiodes 12 for filtering the light by wavelength bands. A layer of material is then coated on and/or over an entire surface of semiconductor substrate 10 including the color filter layers for forming micro-lenses, and subjected to exposure and development to pattern the layer, to form the micro-lenses on and/or over the color filer layers.

As has been described, the method for fabricating a CMOS image sensor in accordance with embodiments has the following advantages. Generally, in a CMOS image sensor, after the interlayer insulating film is formed, the interlayer insulating film is patterned by dry etching for reducing a gap between the micro-lens and the photodiode. However, the patterning by plasma has a problem in that a dark current increases due to plasma damage.

On the contrary, since the method for fabricating a CMOS image sensor in accordance with embodiments performs a fabrication process using the dry etching together with the wet etching, the plasma damage can be controlled, and the dark current can also be prevented. Moreover, the gap between the micro-lens and the photodiode can be reduced, thereby enhancing efficiency of the CMOS image sensor.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a plurality of photodiodes in a semiconductor substrate at fixed intervals;
forming an interlayer insulating film over an entire surface of the semiconductor substrate including the photodiodes;
forming a hard mask film over an entire surface of the interlayer insulating film;
forming a photoresist pattern over the hard mask film for exposing a hard mask film region corresponding to a photodiode region;
etching the hard mask film by performing a first etching process using the photoresist pattern as a mask; and then
selectively etching the interlayer insulating film by performing a second etching process using the etched hard mask film as a mask.

2. The method of claim 1, wherein the first etching process comprises a dry etching process.

3. The method of claim 1, wherein the second etching process comprises a wet etching process.

4. The method of claim 3, wherein the wet etching process is performed using DHF.

5. The method of claim 4, wherein the DHF has a ratio of H₂O:HF of 1 to 5:1.

6. The method of claim 1, wherein the hard mask film comprises PE-Nitride.

7. The method of claim 1, wherein selectively etching the interlayer insulating film comprises forming a trench in the interlayer insulating film.

8. A method comprising:
forming a photodiode in a semiconductor substrate;
forming an insulating film over and contacting the semiconductor substrate and the photodiode, respectively;
forming a hard mask film over and contacting the insulating film;
exposing an area of the insulating film corresponding spatially to the photodiode by performing a first etching process on the hard mask film; and then
forming a trench in the insulating film by performing a second etching process using the etched hard mask film as a mask.

9. The method of claim 8, wherein the photodiode has an uppermost surface that is substantially coplanar to the uppermost surface of the semiconductor substrate.

10. The method of claim 8, wherein the semiconductor substrate comprises a p++ type semiconductor substrate.

11. The method of claim 8, wherein the insulating film comprises an oxide film.

12. The method of claim 11, wherein the oxide film comprises undoped silicate glass.

13. The method of claim 8, wherein the hard mask film comprises PE-Nitride.

14. The method of claim 8, wherein the trench corresponds spatially to the photodiode.

15. The method of claim 8, wherein the first etching process comprises a dry etching process.

16. The method of claim 8, wherein the second etching process comprises a wet etching process.

17. The method of claim 16, wherein the wet etching process is performed using DHF

18. The method of claim 17, wherein the DHF has a ratio of H₂O:HF of 1 to 5:1.

19. A method comprising:
forming a photodiode in a semiconductor substrate;
forming an oxide film over the semiconductor substrate and the photodiode, respectively;
forming a hard mask film over the oxide film;
exposing an area of the oxide film corresponding spatially to the photodiode by performing a dry etching process on the hard mask film; and then forming a trench by performing a wet etching process on the oxide film.

20. The method of claim 19, wherein the oxide film comprises undoped silicate glass and the hard mask film comprises PE-Nitride.
